(19) United States
(12) Patent Application Publication
(10) Pub. No.: US 2001/0028252 A1
(43) Pub. Date: Oct. 11, 2001

(54) IMPEDANCE ADAPTING CIRCUIT

(76) Inventor: PERTTI K. IKALAINEN, HUHMARI (FI)

Correspondence Address: TEXAS INSTRUMENTS INCORPORATED, P O BOX 655474, M/S 3999, DALLAS, TX, 75265

(21) Appl. No.: 08/954,322

(22) Filed: Oct. 17, 1997

Related U.S. Application Data
(60) Provisional application No. 60/028,728, filed on Oct. 18, 1996.

(51) Int. Cl. G01R 27/04

(52) U.S. Cl. 324/637

(57) ABSTRACT

An integrated circuit (10) is provided for adapting the impedance load on a transmission line (11). The integrated circuit (10) includes a detector (16) which can detect a forward outgoing signal and a reflected signal on the transmission line (11). A controller (18) is coupled to the detector (16). The controller (18) may compare the detected forward outgoing signal and the reflected signal. The controller (18) outputs at least one control signal in response to the comparison. An adapter (14), coupled to the controller (18), switches between a plurality of alternate impedance states for the load in response to the control signal.

### TECHNICAL FIELD OF THE INVENTION

The present invention relates generally to signal transmission, and more particularly, to an impedance adapting circuit.

### BACKGROUND OF THE INVENTION

Transmission signals (e.g., microwave signals) carried over a transmission line can be amplified by solid state power amplifiers. Typically, these power amplifiers are designed to perform optimally when an output load on the transmission line is equal to 50 ohms. When the load differs from 50 ohms, the performance of such power amplifiers is degraded. More specifically, if impedance is not matched for a power amplifier, a portion of the amplified signals may be reflected back along the transmission line, thereby reducing the strength of the signal which is actually delivered.

Previously, in order to reduce the signals reflected back toward a power amplifier, a circulator was used between the power amplifier and the amplifier's load. The circulator isolated the amplifier from variations in load impedance in order to match the desired 50-ohm load. Thus, optimal performance of the amplifier was maintained. Circulators, however, were problematic for numerous reasons. For example, circulators could only be implemented using biasing magnets, which are relatively expensive. These magnets are also relatively bulky and heavy, and thus introduced considerable weight and volume. Furthermore, a certain amount of insertion loss was involved with the use of a circulator. Even when a circulator improved the performance of a power amplifier, overall performance of a system incorporating both the power amplifier and the circulator could be degraded because of the insertion loss attributable to the circulator.

### SUMMARY OF THE INVENTION

In accordance with the present invention, an impedance adapting circuit is provided that substantially eliminates or reduces disadvantages and problems associated with prior circuits for adapting the variable impedance load of a transmission line to a power amplifier.

According to an embodiment of the present invention, an integrated circuit is provided for adapting the impedance load on a transmission line. The integrated circuit includes a detector which can detect a forward outgoing signal and a reflected signal on the transmission line. A controller is coupled to the detector. The controller may compare the detected forward outgoing signal and the reflected signal. The controller may output at least one control signal in response to the comparison. An adapter, coupled to the controller, switches between a plurality of alternate impedance states for the load in response to the control signal.

According to another embodiment of the present invention, a solid-state power amplifier having adaptable impedance characteristics is provided. The solid-state power amplifier includes an amplifier for amplifying a forward outgoing signal on a transmission line. A detector, coupled to the transmission line, may detect the forward outgoing signal and a reflected signal on the transmission line. A controller is coupled to the detector. The controller compares the detected forward outgoing signal and the reflected signal, and outputs at least one control signal in response to the comparison. An adapter, coupled to the controller, switches between a plurality of alternate impedance states for the load in response to the control signal.

The present invention provides various technical advantages over prior systems for adapting the impedance of a transmission line to improve performance of a power amplifier. One technical advantage includes providing an impedance adapting circuit which can be implemented as a monolithic microwave integrated circuit (MMIC). Generally, a monolithic microwave integrated circuit is neither bulky nor expensive. Another technical advantage includes providing an impedance adapting circuit which does not introduce a large amount of insertion loss when coupled to a solid-state power amplifier. Other technical advantages are readily apparent to one skilled in the art from the following figures, descriptions, and claims.

### BRIEF DESCRIPTION OF THE DRAWINGS

For a more complete understanding of the present invention and for advantages thereof, reference is now made to the following description taken in conjunction with the accompanying drawings, wherein like reference numerals represent like parts, in which:

FIG. 1 is a simplified block diagram of an impedance adapting circuit constructed in accordance with the teachings of the present invention;

FIG. 2 is a schematic diagram of an exemplary embodiment of an adapter within the impedance adapting circuit shown in FIG. 1; and

FIG. 3 is a schematic diagram of an exemplary embodiment of a detector within the impedance adapting circuit shown in FIG. 1.

### DETAILED DESCRIPTION OF THE INVENTION

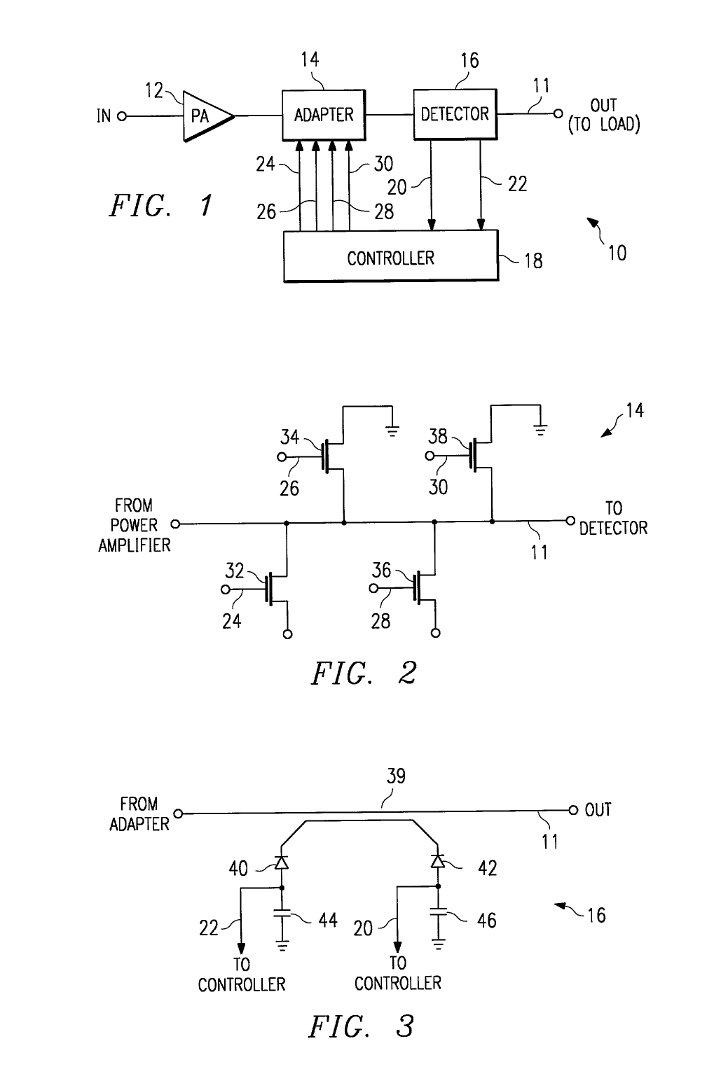

The present invention and its advantages are best understood by referring to FIGS. 1-3 of the drawings, like numerals being used for like and corresponding parts of the various drawings.

FIG. 1 illustrates one embodiment of an impedance adapting circuit 10 constructed in accordance with the teachings of the present invention. Impedance adapting circuit 10 is coupled to a transmission line 11, and generally functions to change the impedance load on transmission line 11 in order to optimize performance of a power amplifier. As shown, impedance adapting circuit 10 may comprise a power amplifier 12, an adapter 14, a detector 16, and a controller 18. In another embodiment, an impedance adapting circuit of the present invention may not include a power amplifier, but rather is inserted between a power amplifier and the load.

Power amplifier 12 may be implemented as a standard solid-state power amplifier. Power amplifier 12 generally functions to amplify the strength of a transmission signal appearing on transmission line 11. Power amplifier 12 may be designed for optimum output power and efficiency for a particular impedance load, such as 50-ohms.

As indicated above, in one embodiment, power amplifier 12 may be integral to impedance adapting circuit 10. Alternatively, in another embodiment, power amplifier 12 may be separate from the impedance adapting circuit of the present invention. In other words, adapter 14, detector 16, and controller 18 are inserted between power amplifier 12 and a load.

Adapter 14 is coupled to power amplifier 12. Adapter 14 functions primarily to change the impedance on transmission line 11 to match the impedance for which power amplifier 12 is designed to operate. In one embodiment, adapter 14 can be switched between a plurality of distinct impedance states to vary the load as seen by power amplifier 12 on transmission line 11. An exemplary embodiment of adapter 14 is illustrated and described below in more detail with reference to FIG. 2.

Detector 16 is coupled to adapter 14. Detector 16 functions primarily to detect forward outgoing signals and reflected signals along transmission line 11. With regard to FIG. 1, forward outgoing signals move from left to right along transmission line 11; reflected signals move from right to left. Theoretically, the delivery of the forward outgoing signals is optimized when the reflected signals are minimized. In response to the detected signals, detector 16 may output one or more detection signals over exemplary connections 20 and 22. An exemplary embodiment of detector 16 is illustrated and described below in more detail with reference to FIG. 3.

Controller 18 is coupled to detector 16 and adapter 14. Controller 18 may be formed as one or more logic circuits, the implementation of which would be obvious to one of ordinary skill in the art based upon functions of controller 18 as described below. Controller 18 functions primarily to direct the change of impedance states in adapter 14 in response to the detection of forward outgoing and reflected signals by detector 16. For this purpose, controller 18 may output one or more control signals over exemplary connections 24-30.

All elements of impedance adapting circuit 10—including power amplifier 12, adapter 14, detector 16, and controller 18—may be implemented as a monolithic microwave integrated circuit, such as, for example, a Gallium Arsenide (GaAs) type technology. Because there is no need for a bulky, expensive biasing magnet, the present invention substantially reduces the weight, volume, and cost normally associated with impedance adapting circuitry. Furthermore, due to the compact nature of a monolithic microwave integrated circuit, impedance adapting circuit 10 can be added with a relatively low insertion loss.

FIG. 2 is a schematic diagram of an exemplary embodiment of adapter 14 within impedance adapting circuit 10. In this embodiment, adapter 14 includes a plurality of switches 32-38, which are coupled to transmission line 11. In a preferred embodiment, the distance along transmission line 11 between the connections for switch 32 and switch 34 is equal to one-sixteenth of the wavelength of a transmitted signal. Likewise, the distance along transmission line 11 between the connections for switches 34 and 36, and the distance between the connections for switches 36 and 38 are also preferably one-sixteenth of a wavelength. As shown, switches 32-38 may be implemented as field effect transistors (FETs). Alternatively, switches 32-38 may be implemented as P-I-N diodes. At least a portion of these switches, such as switches 32 and 36, may be incorporated into open stub connections—i.e., connections which are neither grounded nor connected to a power source. Another portion of these switches, such as switches 34 and 38, may be incorporated into shorted stub connections—i.e., connections which are grounded. Switches 32-38 may be turned on and off in order to create various impedance states on transmission line 11. Stated differently, at a particular moment, one of sixteen alternate impedance states may be generated depending upon the combination of switches 32-38 which are turned on and turned off. One of ordinary skill will understand that the impedance values for the sixteen states can be varied by adjusting different parameters, such as the width of the connections. Switches 32-38 receive control signals from controller 18 over connections 24-30. A separate control signal may be provided for each switch. The control signals operate to turn on and turn off switches 32-38.

FIG. 3 is a schematic diagram of an exemplary embodiment of detector 16 shown in FIG. 1. In this embodiment, detector 16 includes integrated coupler 39, diodes 40 and 42, and capacitors 44 and 46. Integrated coupler 39 functions to detect forward outgoing signals and reflected signals on transmission line 11. Each of diodes 40 and 42 may be implemented as a Schottky diode. Diodes 40 and 42 are operable to rectify the signals detected by integrated coupler 39. The rectified signals produce voltages which are proportional to the forward outgoing and reflected signals. The voltages are output by detector 16 as detection signals, over exemplary connections 20 and 22. Capacitors 44 and 46 are coupled between diodes 40 and 42, respectively, and ground.

In operation, impedance adapting circuit 10 receives a transmission signal on transmission line 11 at power amplifier 12. Power amplifier 12 amplifies the received transmission signal to produce a forward outgoing amplified signal. In detector 16, integrated coupler 39 detects the relative strength of the forward outgoing signal and any signals which are reflected back on transmission line 11. Diodes 40 and 42 rectify the detected signals. The rectified signals are output as detector signals over connections 20 and 22. Controller 18 receives the detector signals and, in response, generates one or more control signals for adapter 14. Adapter 14 receives the control signals from controller 18 over connections 24-30. The control signals turn on and turn off various switches 32-38, thereby adjusting the impedance state of adapter 14 for transmission line 11. The impedance state is selected which minimizes the reflected signals along transmission line 11, thereby optimizing the performance of power amplifier 12.

Although the present invention and its advantages have been described in detail, it should be understood that various changes, substitutions, and alterations can be made therein without departing from the spirit and scope of the invention as defined by the appended claims.

What is claimed is:

1. An integrated circuit for adapting the impedance load on a transmission line, comprising:
a detector operable to detect a forward outgoing signal and a reflected signal on the transmission line;
a controller coupled to the detector, the controller operable to compare the detected forward outgoing signal and the reflected signal, the controller further operable to output at least one control signal in response to the comparison; and
an adapter coupled to the controller, the adapter operable to switch between a plurality of alternate impedance states for the load in response to the at least one control signal.

2. The integrated circuit of claim 1, further comprising an amplifier operable to amplify the forward outgoing signal.

3. The integrated circuit of claim 1, wherein the detector further comprises an integrated coupler operable to detect the forward outgoing signal and the reflected signal on the transmission line.

4. The integrated circuit of claim 1, wherein the detector further comprises:
a first diode operable to rectify the one of the detected forward outgoing signal and the reflected signal to generate a first detector signal; and
a second diode operable to rectify the other of the detected forward outgoing signal and the reflected signal to generate a second detector signal.

5. The integrated circuit of claim 4, wherein the first and second diodes further comprise Schottky diodes.

6. The integrated circuit of claim 1, wherein the adapter further comprises at least one switch responsive to the at least one control signal from the controller.

7. The integrated circuit of claim 1, wherein the adapter further comprises at least one field effect transistor responsive to the at least one control signal from the controller.

8. The integrated circuit of claim 1, wherein the adapter comprises at least one P-I-N diode responsive to the at least one control signal from the controller.

9. The integrated circuit of claim 1, wherein the adapter further comprises:
a first open stub circuit coupled to the transmission line, the first open stub circuit having a first switch responsive to a first control signal from the controller; and
a first shorted stub circuit coupled to the transmission line downstream of the first open stub, the first shorted stub circuit having a second switch responsive to a second control signal from the controller.

10. The integrated circuit of claim 9, wherein the adapter further comprises:
a second open stub circuit coupled to the transmission line downstream of the first shorted stub, the second open stub circuit having a third switch responsive to a third control signal from the controller; and
a second shorted stub circuit coupled to the transmission line downstream of the second open stub, the second shorted stub circuit having a fourth switch responsive to a fourth control signal from the controller.

11. The integrated circuit of claim 1, wherein the integrated circuit is implemented as Gallium Arsenide type technology.

12. A solid-state power amplifier having adaptable impedance characteristics, comprising:
an amplifier operable to amplify a forward outgoing signal on a transmission line;
a detector coupled to the transmission line, the detector operable to detect the forward outgoing signal and a reflected signal on the transmission line;
a controller coupled to the detector, the controller operable to compare the detected forward outgoing signal and the reflected signal, the controller further operable to output at least one control signal in response to the comparison; and
an adapter coupled to the controller, the adapter operable to switch between a plurality of alternate impedance states for the load in response to the at least one control signal.

13. The power amplifier of claim 12, wherein the detector further comprises an integrated coupler operable to detect the forward outgoing signal and the reflected signal on the transmission line.

14. The power amplifier of claim 12, wherein the detector further comprises:
a first diode operable to rectify the one of the detected forward outgoing signal and the reflected signal to generate a first detector signal; and
a second diode operable to rectify the other of the detected forward outgoing signal and the reflected signal to generate a second detector signal.

15. The power amplifier of claim 14, wherein each of the first and second diodes comprises a Schottky diode.

16. The power amplifier of claim 12, wherein the adapter further comprises:
a first open stub circuit coupled to the transmission line, the first open stub circuit having a first switch responsive to a first control signal from the controller;
a first shorted stub circuit coupled to the transmission line downstream of the first open stub, the first shorted stub circuit having a second switch responsive to a second control signal from the controller;
a second open stub circuit coupled to the transmission line downstream of the first shorted stub, the second open stub circuit having a third switch responsive to a third control signal from the controller; and
a second shorted stub circuit coupled to the transmission line downstream of the second open stub, the second shorted stub circuit having a fourth switch responsive to a fourth control signal from the controller.

17. The power amplifier of claim 16, wherein each of the first, second, third, and fourth switches comprises a field-effect transistor.

18. The power amplifier of claim 16, wherein each of the first, second, third, and fourth switches comprises a P-I-N diode.

19. The power amplifier of claim 12, wherein the power amplifier is implemented as Gallium Arsenide type technology.
